(19) United States
(12) Patent Application Publication
(10) Pub. No.: US 2023/0336149 A1
(43) Pub. Date: Oct. 19, 2023

(54) MEMS DEVICE AND FABRICATION METHOD THEREOF

(71) Applicant: Ningbo Semiconductor International Corporation, Ningbo (CN)

(72) Inventors: Wei LI, Ningbo (CN); Herb He HUANG, Ningbo (CN); Hailong LUO, Ningbo (CN)

(21) Appl. No.: 18/141,454

(22) Filed: Apr. 30, 2023

Related U.S. Application Data
(63) Continuation of application No. PCT/CN2021/143480, filed on Dec. 31, 2021.

(30) Foreign Application Priority Data
Dec. 31, 2020 (CN) 202011636676.1

(51) Int. Cl. H03H 9/05; H03H 3/02; H03H 9/56

(52) U.S. Cl. CPC H03H 9/0547; H03H 3/02; H03H 9/564; H03H 2003/021; H03H 2003/027

(57) ABSTRACT

A fabrication method of a MEMS device includes providing a logic circuit chip including a substrate and a CMOS circuit disposed on the substrate, forming a first structural layer on the logic circuit chip, and forming a first isolation groove on the first structural layer; providing a BAW filter including a supporting substrate, a support layer formed on the supporting substrate, and a piezoelectric stack structure, the piezoelectric stack structure forming a second cavity with the supporting substrate and the support layer, and piezoelectric stack structure including a second electrode, a piezoelectric layer, and a first electrode that are sequentially stacked; and bonding the BAW filter to the first structural layer on the logic circuit chip, such that the first isolation groove is disposed between the logic circuit chip and the BAW filter to form a first cavity where an effective resonance region of the piezoelectric stack structure is located.

### CROSS-REFERENCE TO RELATED APPLICATION

This application is a continuation application of PCT Patent Application No. PCT/CN2021/143480, filed on Dec. 31, 2021, which claims priority to Chinese Patent Application No. 202011636676.1, filed on Dec. 31, 2020, the entirety of all of which is incorporated herein by reference.

### TECHNICAL FIELD

The present disclosure relates to the technical field of microelectromechanical systems (MEMS) device and, more particularly, to a MEMS device and a fabrication method thereof.

### BACKGROUND

Microelectromechanical system (MEMS) and integrated circuit (IC) are currently two most important development areas of the semiconductor industry. Driven by the global technology development, integration of MEMS and IC has become an inevitable trend. The integration includes three methods, namely, monolithic integration, semi-hybrid (bonding) integration, and hybrid integration. The monolithic integration refers to fabricating a MEMS structure and a complementary metal-oxide semiconductor (CMOS) structure on a same chip. The hybrid integration refers to fabricating the MEMS structure and the CMOS structure on separate dies and packaging them together into one device in which the MEMS bare chip with bumps is flipped and is soldered or wire-bonded to connect to the IC chip to form a system-in-package (SIP). The semi-hybrid integration refers to using a three-dimensional integration technology to three-dimensionally integrate the MEMS structure and the CMOS structure. The monolithic integration is an important development direction of the integration technology of the MEMS and IC, and provides many advantages for radio frequency (RF) thin film bulk acoustic wave (BAW) filters. Firstly, a processing circuit is close to a microstructure such that detected signals and transmitted signal are highly accurate. Secondly, the integrated system is small in volume and low in power consumption. Thirdly, the number of components and the number of package pins are reduced, resulting in higher reliability.

The existing RF BAW filter fabrication technology often integrates filters, drivers, and processing circuits together into one SIP. SIP refers to integrating multiple functional chips into one package and connecting the chips through the wire-bonding of the substrates. Long interconnection and low integration density of the SIP affect filter signal transmission complicate the fabrication process. In some fabrication processes, the logic circuit chip and the filter chip are fabricated on two different wafers. The two chips are integrated together in a form of system-level packaging, and the two chips are interconnected through wiring provided by the system-level packaging. In some other fabrication processes, the logic circuit chip and the filter chip are soldered onto a same printed circuit board (PCB), and the two chips are interconnected through wiring provided by the PCB. In either fabrication process, the packaged device is large in volume and low in integration density.

Therefore, current MEMS devices have the technical problem of large package volume and low integration density.

### SUMMARY

One aspect of the present disclosure provides a method for fabricating a microelectromechanical systems (MEMS) device. The method includes: providing a logic circuit chip including a substrate and a complementary metal-oxide semiconductor (CMOS) circuit disposed on the substrate, forming a first structural layer on the logic circuit chip, and forming a first isolation groove on the first structural layer; providing a bulk acoustic wave (BAW) filter including a supporting substrate, a support layer formed on the supporting substrate, and a piezoelectric stack structure, the piezoelectric stack structure forming a second cavity with the supporting substrate and the support layer, and piezoelectric stack structure including a second electrode, a piezoelectric layer, and a first electrode that are sequentially stacked; and bonding the BAW filter to the first structural layer on the logic circuit chip, such that the first isolation groove is disposed between the logic circuit chip and the BAW filter to form a first cavity where an effective resonance region of the piezoelectric stack structure is located.

Another aspect of the present disclosure provides a microelectromechanical systems (MEMS) device. The MEMS device includes: a logic circuit chip including a complementary metal-oxide semiconductor (CMOS) circuit; a first structural layer disposed above the logic circuit chip; and a bulk acoustic wave (BAW) filter disposed above the first structural layer. A bonding interface layer is formed between the BAW filter and the first structural layer. The BAW filter includes a supporting substrate, an acoustic reflective structure disposed on a surface of the supporting substrate, and a piezoelectric stack structure disposed on the acoustic reflective structure. The first structural layer includes a first cavity. An effective resonance region of the piezoelectric stack structure is disposed in the first cavity.

### BRIEF DESCRIPTION OF THE DRAWINGS

To more clearly illustrate the technical solution of the present disclosure, the accompanying drawings used in the description of the disclosed embodiments are briefly described below. The drawings described below are merely some embodiments of the present disclosure. Other drawings may be derived from such drawings by a person with ordinary skill in the art without creative efforts and may be encompassed in the present disclosure.

FIG. 1 is a structural schematic diagram of an exemplary MEMS device according to some embodiments of the present disclosure; and

FIGS. 2-11 are structural schematic diagrams of a MEMS device at various stages during an exemplary method for fabricating MEMS device according to some embodiments of the present disclosure.

### DETAILED DESCRIPTION OF THE EMBODIMENTS

In order to make the objectives, technical solutions, and advantages of the present disclosure clearer, the present disclosure will be further described in detail below with reference to the accompanying drawings. Obviously, the described embodiments are only some of the embodiments of the present disclosure, not all of the embodiments. Based on the embodiments of the present disclosure, all other embodiments obtained by those of ordinary skill in the art without creative efforts shall fall within the scope of the present disclosure.

The terms “first”, “second”, etc. in the specification and claims are used to distinguish between similar elements and not necessarily to describe a specific order or chronological order. It should be understood that the terms so used are interchangeable under appropriate circumstances, for example, to enable the embodiments of the present disclosure described herein to be operated in other sequences than described or illustrated herein. Similarly, if a method described herein includes a series of steps, the order in which these steps are presented is not necessarily the only order in which these steps can be performed, and some described steps may be omitted and/or some additional steps not described herein can be added. If the components in a certain drawing are the same as those in other drawings, although these components can be easily identified in all the drawings, in order to make the description of the drawings clearer, the specification will not mark reference numerals for all the same components in each figure.

### Exemplary Embodiment 1

The present disclosure provides a method for fabricating a MEMS device. The method includes the following processes.

At S01, a logic circuit chip is provided. The logic circuit chip includes a substrate and a CMOS circuit disposed on the substrate. A first structural layer is formed on the logic circuit chip, and is etched to form a first isolation groove.

At S02, a BAW filter is provided. The BAW filter includes a supporting substrate, a support layer formed on a surface of the supporting substrate, and a piezoelectric stack structure configured to form a second cavity together with the supporting substrate and the support layer. The piezoelectric stack structure includes a second electrode, a piezoelectric layer, and a first electrode stacked sequentially.

At S03, the BAW filter is bonded to the first structural layer on the logic circuit chip, such that a first isolation groove is interposed between the logic circuit chip and the BAW filter to form a first cavity.

At S04, an effective resonance region of the piezoelectric stack structure is located in the first cavity.

The above steps do not represent any order of execution.

FIGS. 2-11 are structural schematic diagrams of a MEMS device at various stages during an exemplary method for fabricating MEMS device according to some embodiments of the present disclosure. With reference to FIGS. 2-11, the method for fabricating the MEMS device provided by embodiments of the present disclosure is described in detail below.

Referring to FIGS. 2-6, a logic circuit chip is provided. The logic circuit chip includes a substrate and a CMOS circuit disposed on the substrate. A first structural layer is formed on the logic circuit chip. The first structural layer is etched to form the first isolation groove. Processes of forming the first isolation groove are illustrated with reference to FIGS. 2-6.

Referring to FIG. 2, the logic circuit chip is provided.

The processes of forming the logic circuit chip includes the following processes. A substrate 10 is provided. The substrate 10 includes a first surface and a second surface arranged opposite to each other. The substrate 10 includes at least one of materials such as silicon (Si), germanium (Ge), silicon germanium (SiGe), silicon carbon (SiC), silicon germanium carbon (SiGeC), SOI substrate, indium arsenide (InAs), gallium arsenide (GaAs), indium phosphide (InP), or other III/V compound semiconductors. The substrate 10 may also include multilayer structures including the above semiconductors. In some embodiments, the resistivity of the substrate 10 is greater than 1K ohm·cm, which generates a relatively large electrical impedance, and hence reduces interference to high-frequency electromagnetic waves of the BAW filter and improves device performance. A CMOS circuit 11 is formed on the first surface of the substrate 10. A dielectric layer 20 is further formed on the first surface of the substrate 10 to cover the first surface of the substrate 10 and the CMOS circuit 11.

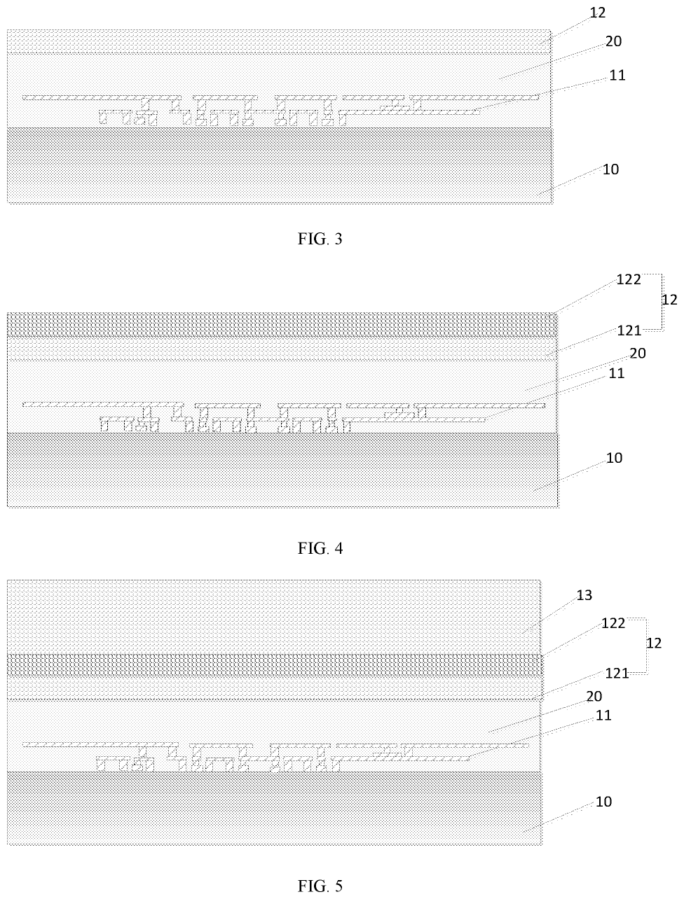

Referring to FIGS. 3-4, a passivation layer 12 is formed on the logic circuit chip.

Forming the passivation layer on the logic circuit chip provides a function of preventing dust, moisture, and corrosion from affecting the logic circuit chip, and also prevents liquids or vapors from eroding the CMOS circuit in subsequent fabrication processes.

Forming the passivation layer 12 includes the processes illustrated in FIGS. 3-6.

Referring to FIG. 3, an oxide layer 121 is formed on the dielectric layer 20.

The material of the oxide layer 121 includes at least one insulating material, such as silicon oxide, silicon oxynitride, and silicon nitride. By forming the oxide layer 121 on a surface of the BAW filter, the function of preventing the dust and moisture from affecting the logic circuit chip is improved.

Referring to FIG. 4, an etch stop layer 122 is formed on the oxide layer 121. The etch stop layer 122 and the oxide layer 121 together form the passivation layer 12.

The material of the stop layer 122 includes, but is not limited to, silicon nitride and silicon oxynitride. In some embodiments, the etch stop layer 122 is made of silicon nitride. Silicon nitride has high density and high strength, capable of improving the function of preventing the moisture and corrosion from affecting the logic circuit chip.

In addition, on one hand, the etch stop layer 122 may be used to enhance structural stability of the logic circuit chip. On the other hand, the etch stop layer 122 has an etching rate lower than the oxide layer 121, helps prevent over-etching in a subsequent process of etching the first structural layer to form the first isolation groove, and protects the surface of the logic circuit chip thereunder from damages, thereby improving the device performance and reliability.

In some other embodiments, the passivation layer 12 may only include one of the oxide layer 121 and the etch stop layer 122, or may have different structures, which are not limited herein.

Referring to FIG. 5, a first structural layer 13 is formed on the passivation layer 12.

The first structural layer 13 may include a photolithographically curable organic film, metal, silicon oxide, silicon oxynitride, silicon carbonitride, ethyl silicate, or a combination thereof. In some embodiments, the first structural layer 13 includes silicon oxide. A thickness of the first structural layer 13 is ranging about 3 μm to 10 μm. Subsequent bonding of the logic circuit chip with the BAW filter needs to reach a certain thickness, and the first isolation groove subsequently formed on the first structural layer 13 also needs to have a certain depth. Thus, in some embodiments, limiting the thickness of the first structural layer 13 to the range about 3 μm to 10 μm facilitates the subsequent bonding of the logic circuit chip and the BAW filter, ensures a desired acoustic reflection efficiency of the BAW filter, isolates an interference effect of the logic circuit chip, and saves cost. In some other embodiments, the thickness of the first structural layer 13 may also be higher or lower than this range.

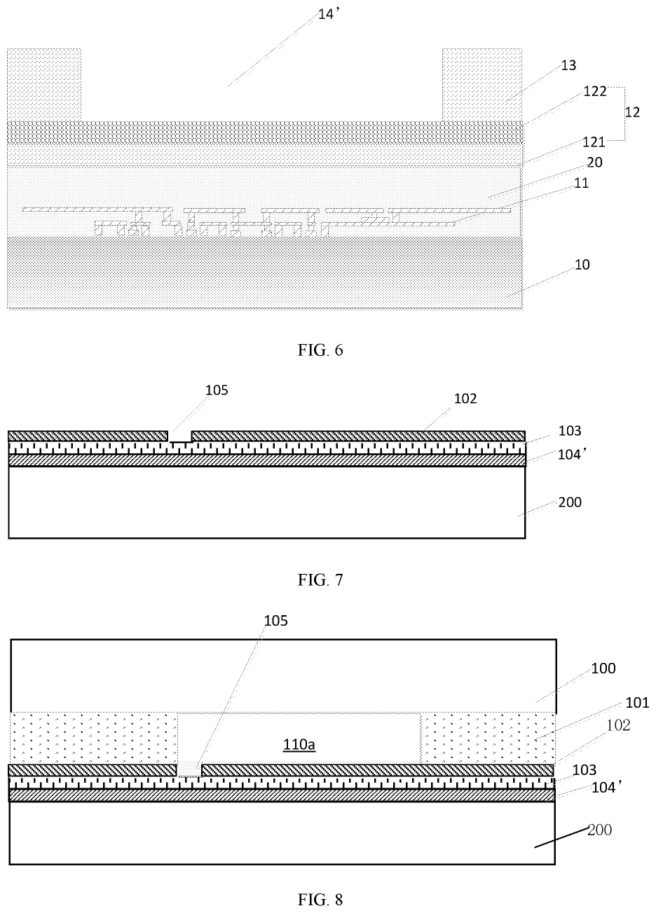

Referring to FIG. 6, the first structural layer 13 is etched to form a first isolation groove 120a.

In some embodiments, the first isolation groove 120a′ penetrates through the first structural layer 13. A depth of the first isolation groove 120a′ is equal to a thickness of the first structural layer 13. In addition, after the first isolation groove 120a′ is formed, the first structural layer 13 is planarized, which enhances the strength of the subsequent bonding with the BAW filter and improves depth uniformity of the first isolation groove 120a′. Thus, the reflective performance of a subsequently formed first cavity can be improved, and the performance of the BAW filter can be improved.

In some other embodiments, the first isolation groove 120a′ may not penetrate the first structural layer 13, which may be determined according to actual needs.

Referring to FIGS. 7-9, a BAW filter is provided. The BAW filter includes a supporting substrate, a support layer formed on the supporting substrate, and a piezoelectric stack structure configured to form a second cavity together with the supporting substrate and the support layer. The piezoelectric stack structure includes a second electrode, a piezoelectric layer, and a first electrode stacked sequentially. Processes of forming the BAW filter are illustrated with reference to FIGS. 7-9.

Referring to FIG. 7, a temporary substrate 200 is provided.

The temporary substrate 200 may be any suitable substrate well known to those skilled in the art, and may be made of at least one of silicon (Si), germanium (Ge), silicon germanium (SiGe), arsenide Indium (Ins), indium phosphide (InP), or other III/V compound semiconductors. The temporary substrate 200 may be a multilayer structure including the above semiconductors, such as silicon-on-insulator (SOI), stacked silicon-on-insulator (SSOI), stacked silicon germanium-on-insulator (S—SiGeOI), silicon germanium-on-insulator (SiGeOI), and germanium-on-insulator (GeOI). The temporary substrate 200 may also be a double side polished silicon (DSP) wafer, an aluminum oxide ceramic substrate, or a quartz or glass substrate, etc. In some embodiments, the temporary substrate 200 is a P-type high-resistance single crystal silicon wafer with a <100> crystal orientation.

A second electrode layer 104′, a piezoelectric layer 103, and a first electrode 102 are sequentially formed on the temporary substrate 200.

The materials of the second electrode layer 104′ and the first electrode 102 may be any suitable conductive material or semiconductor material well known to those skilled in the art. The conductive material may be a metal material with conductive properties, for example, molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), gold (Au), osmium (Os), rhenium (Re), palladium (Pd), and other metals or a stack of the above metals. The semiconductor material may be Si, Ge, SiGe, SiC, or SiGeC, etc. The second electrode layer 104′ and the first electrode 102 may be formed by a physical vapor deposition method such as magnetron sputtering and evaporation or a chemical vapor deposition method. The material of the piezoelectric layer 103 may include a piezoelectric material with a wurtzite crystal structure such as aluminum nitride (AlN), zinc oxide (ZnO), lead zirconate titanate (PZT), lithium niobate (LiNbO3), quartz, potassium niobate (KNbO3), lithium tantalum acid (LiTaO3), and a combination thereof. When the piezoelectric layer 103 includes aluminum nitride (AlN), the piezoelectric layer 103 may further include a rare earth metal such as at least one of scandium (Sc), erbium (Er), yttrium (Y), or lanthanum (La). In addition, when the piezoelectric layer 103 includes aluminum nitride (AlN), the piezoelectric layer 103 may further include a transition metal such as at least one of zirconium (Zr), titanium (Ti), manganese (Mn), or hafnium (Hf). The piezoelectric layer 103 may be deposited and formed by any suitable method known to those skilled in the art, such as chemical vapor deposition, physical vapor deposition, or atomic layer deposition. In some embodiments, the second electrode layer 104′ and the first electrode 102 are made of metal molybdenum (Mo), and the piezoelectric layer 103 is made of aluminum nitride (AlN).

In some embodiments, after the first electrode 102 is formed, the first electrode 102 is etched to form a first groove 105 penetrating through the first electrode 102. The first groove 105 is located in a subsequently formed first cavity 120a, and the sidewall of the first groove 105 may be inclined or vertical. In some embodiments, the sidewall of the first groove 105 forms a right angle with a plane where the piezoelectric layer 103 is located (the longitudinal cross-section of the first groove 105. A vertical cross-section (along a film thickness direction) is a rectangular shape. In some other embodiments, the sidewall of the first groove 105 forms an obtuse angle with the plane where the piezoelectric layer 103 is located. An orthogonal projection of the first groove 105 on the plane where the piezoelectric layer 103 is located is a half-ring shape or a half-ring-like polygon shape.

Referring to FIG. 8, a supporting substrate 100 including the second cavity 110a is formed on the piezoelectric layer. The supporting substrate 100 covers part of the first electrode 102. The effective resonance region of the first electrode 102 is located within a boundary of an area enclosed by the second cavity 110a.

The support layer 101 is also formed on the piezoelectric layer. The support layer 101 is bonded to the supporting substrate 100 and forms the second cavity 110a with the piezoelectric layer. The second cavity 110a exposes the supporting substrate 100. In some embodiments, the second cavity 110a is an annular closed cavity. The second cavity 110a may be formed by etching the support layer 101 through an etching process. However, the present disclosure is not limited thereto. It should be noted that, the support layer 101 is bonded to the supporting substrate 100 through a bonding process, and the bonding process may include: metal bonding, covalent bonding, adhesive bonding, and fusion bonding. In some embodiments, the support layer 101 and the supporting substrate 100 are bonded together through a bonding layer. The material of the bonding layer may include silicon oxide, silicon nitride, silicon oxynitride, silicon carbonitride, and ethyl silicate.

In some embodiments, a shape of a bottom surface of the second cavity 110a is rectangular. In some other embodiments, the shape of the bottom surface of the second cavity 110a on the first electrode 102 may also be circular, oval, or polygons other than rectangles, such as pentagons, hexagons, etc. The material of the support layer 101 may be any suitable dielectric material, including but not limited to one of silicon oxide, silicon nitride, silicon oxynitride, and silicon carbonitride. The materials of the support layer 101 and the bonding layer may be the same.

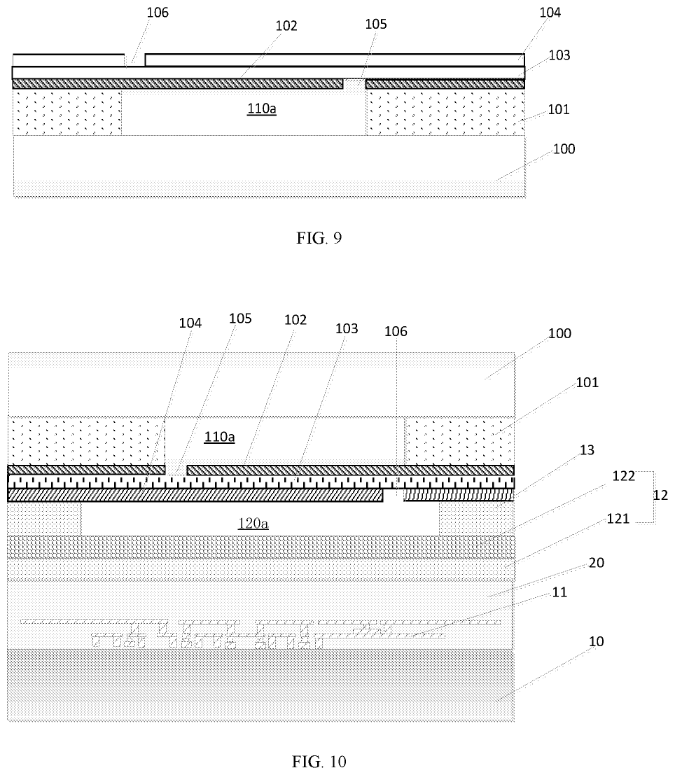

Referring to FIG. 9, the temporary substrate 200 is removed.

After the temporary substrate 200 is removed, a patterning process is performed on the second electrode layer 104′ to form a second electrode 104. The first electrode, the piezoelectric layer, and the second electrode together form the piezoelectric stack structure. The second electrode 104 is etched to form a second groove 106 penetrating through the second electrode 104. The second groove 106 is formed on a side opposite to the first groove 105. In some embodiments, two junctions of orthogonal projections of the first groove 105 and the second groove 106 on the supporting substrate 100 meet with each other to form a closed irregular polygon. For the structure and formation method of the second groove 106, reference can be made to the structure and formation method of the first groove 105. In some other embodiments, only one of the first groove 105 and the second groove 106 may be formed separately. Two ends of the first groove 105 are arranged opposite to two ends of the second groove 106, such that the two junctions of the orthogonal projections of the first groove 105 and the second groove 106 on the supporting substrate 100 meet with each other or may be separated by a gap. In some embodiments, the orthogonal projections of the first groove 105 and the second groove 106 on the supporting substrate 100 are closed figures. The first electrode 102, the piezoelectric layer 103, and the second electrode 104 above the second cavity 120a have an overlapping area in a direction perpendicular to the supporting substrate 100. The overlapping area located between the first groove 105 and the second groove 106 is an effective resonance region of the BAW filter. The effective resonance region of the BAW filter is defined by the first groove 105 and the second groove 106. The first groove 105 and the second groove 106 penetrate through the first electrode 102 and the second electrode 104, respectively. The piezoelectric layer 103 remains intact without being etched, which ensures the structural strength of the BAW filter and improves the yield of the BAW filter.

The effective resonance region is a region where the first electrode 102, the piezoelectric layer 103, and the second electrode 104 overlap with each other in the direction perpendicular to a surface of the piezoelectric stack structure.

Referring to FIG. 10, after the BAW filter is formed, based on FIG. 6, the BAW filter is bonded to the first structural layer 13 on the logic circuit chip, such that the first isolation groove 120a′ is sandwiched between the logic circuit chip and the BAW filter to form the first cavity 120a.

The effective resonance region of the piezoelectric stack structure is located in the first cavity 120a.

It should be noted that the first structural layer 13 is bonded to the BAW filter through a bonding process. The bonding process includes: metal bonding, fusion bonding, pressure bonding, adhesion, covalent bonding, and atomic bonding, etc. In some embodiments, the first structural layer 13 and the BAW filter are bonded together through the bonding layer. The material of the bonding layer includes silicon oxide, silicon nitride, silicon oxynitride, silicon carbonitride, and ethyl silicate. The bonding process may be performed in a vacuum ranging between 1 mbar to 10 mbar, which ensures that a pressure difference between the inside and the outside of the first cavity is in an appropriate range during the bonding process, and pressures of the first cavity and the second cavity remain balanced. Thus, any one-sided force on the piezoelectric stack structure can be avoided, and the performance of the BAW filter can be improved.

In some embodiments, the shape of the bottom surface of the first cavity 120a is a rectangle. But in some other embodiments, the shape of the first cavity 120a may also be a circle, an ellipse, or a polygon other than a rectangle, such as a pentagon, and a hexagon, etc.

The first structural layer 13 with the first isolation groove 120a′ is formed on the logic circuit chip. The BAW filter is bonded to the first structural layer 13 on the logic circuit chip through the bonding process to form the first cavity 120a. A vertical integration of the BAW filter and the logic circuit chip is achieved at a device fabrication stage, which saves a back-end system level packaging process, simplifies the fabrication process, reduces a packaging volume of the entire system, and substantially improves integration density. The BAW filter is bonded to the logic circuit chip at a wafer-level stage of the device fabrication to achieve batch integration, which saves a substrate wafer in a conventional process for fabricating the BAW filter, and reduces production costs. In addition, the process for fabricating the BAW filter is streamlined, and a process for forming a cavity on the piezoelectric stack structure of the BAW filter is avoided. Thus, the piezoelectric stack structure does not need a pre-configured protection layer and is prevented from being damaged by an etching process, thereby improving the device performance. The effective resonance region of the piezoelectric stack structure is located in the first cavity 120a, such that upper and lower surfaces of the effective resonance region are completely exposed in the air, which effectively improves a quality factor of the BAW filter.

Further, at least one of the logic circuit chip and the BAW filter is formed on a wafer, and the bonding process, subsequent electrical connections, and other processes are completed on the wafer. Thus, a requirement of simultaneously fabricating different frequency band filters on one wafer is achieved, process complexity is reduced, and production yield is substantially increased.

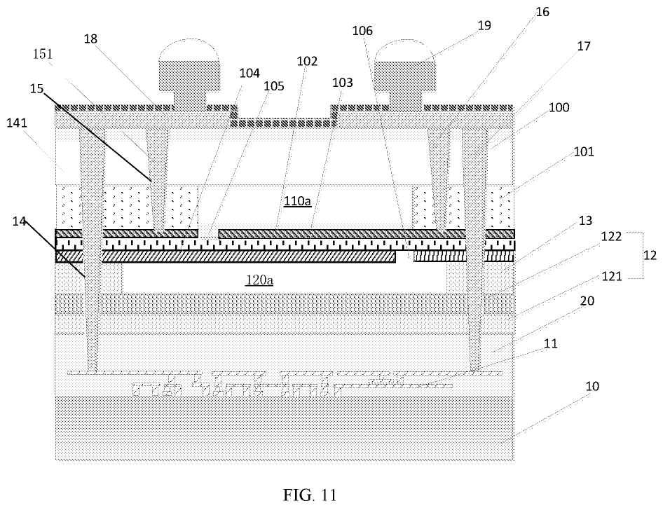

Referring to FIG. 11, after the BAW filter and the logic circuit chip are bonded together, the fabrication method further includes: forming a first electrical connection structure 14 and a fourth electrical connection structure 17 that electrically connect the logic circuit chip to an external circuit, and forming a second electrical connection structure 15 and a third electrical connection structure 16 that electrically connect the BAW file to another external circuit.

The above electrical connection structures are formed separately for the BAW filter and the logic circuit chip to electrically connect to the respective external circuits thereof. In this way, the BAW filter and the logic circuit chip not only are electrically connected with each other but also are electrically connected to the respective external circuits thereof. Thus, interconnection distances can be short, signal transmission speeds can be fast, signal loss can be small, and the performance of MEMS devices can be improved.

The process for forming the first electrical connection structure 14 includes: forming a first interconnection hole (not shown) through an etching process, the first interconnection hole penetrating from one side of the supporting substrate 100 and extending to the CMOS circuit 11 of the logic circuit chip; and forming a first conductive interconnection layer 141 in the first interconnection hole, the first conductive interconnection layer 141 covering an inner surface of the first interconnection hole.

The process for forming the second electrical connection structure 15 includes: forming a second interconnection hole (not shown) by an etching process, the second interconnection hole penetrating from one side of the supporting substrate 100 and extending to the outside of the effective resonance region of the piezoelectric stack structure on the first electrode 102; and forming a second conductive interconnection layer 151 in the second interconnection hole, the second conductive interconnection layer 151 covering an inner surface of the second interconnection hole.

After the first electrical connection structure 14 and the second electrical connection structure 15 are formed, an interconnection line 18 is formed on the surface of the supporting substrate 100. An insulating layer is formed on the interconnection line 18 to cover the interconnection line 18 and the surface of the supporting substrate 100. A conductive bump 19 is arranged on the surface of the supporting substrate 100 and electrically connected to the interconnection line 18. The conductive bump 19 is electrically connected to the external circuits. The first conductive interconnection layer 141 and the second conductive interconnection layer 151 are electrically connected to the interconnection line 18.

In some embodiments, the first conductive interconnection layer 141 includes a first plug, and the second conductive interconnection layer 151 includes a second plug.

Specifically, one end of the first plug is connected to the CMOS circuit 11, and the other end of the first plug is connected to the interconnection line 18. The interconnection line 18 is used to connect to the external circuits. One end of the second plug is connected to the first electrode 102 outside the effective resonance region for electrically connecting to the second electrode 104 inside the effective resonance region. The third electrical connection structure 16 is used for electrically connecting to the first electrode 102 of the effective resonance region. After the first electrode 102 and the second electrode 104 are energized, a pressure difference is generated on the upper and lower surfaces of the piezoelectric layer 103 to form a standing wave oscillation. The fourth electrical connection structure 17 is used to connect to the CMOS circuit 11. The third electrical connection structure 16 may be formed in the same way as the second electrical connection structure 15. The fourth electrical connection structure 17 may be formed in the same way as the first electrical connection structure 14. The descriptions thereof are omitted herein.

### Exemplary Embodiment 2

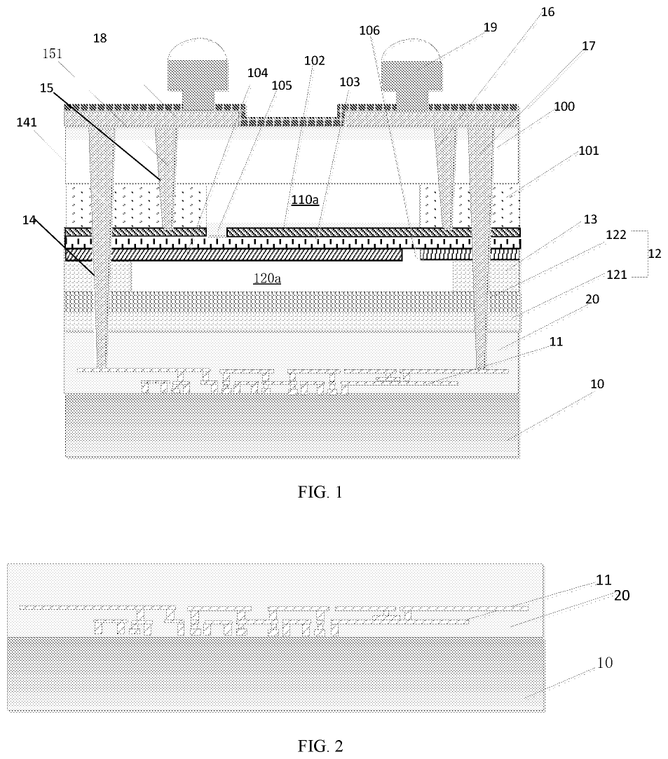

The present disclosure also provides a MEMS device. FIG. 1 is a structural schematic diagram of an exemplary MEMS device according to some embodiments of the present disclosure. As shown in FIG. 1, the MEMS device includes a logic circuit chip including a CMOS circuit 11, a first structural layer 13 disposed above the logic circuit chip, and a BAW filter disposed above the first structural layer 13. A bonding interface layer is disposed between the BAW filter and the first structural layer 13. The BAW filter includes a supporting substrate 100, an acoustic reflective structure disposed on the surface of the supporting substrate 100, and a piezoelectric stack structure disposed on the acoustic reflective structure. The first structural layer 13 includes a first cavity 120a. An effective resonance region of the piezoelectric stack structure is located in the first cavity 120a.

The BAW filter may be one of a thin film BAW resonator and a solid-state assembled resonator. When the acoustic reflective structure includes a cavity, the BAW filter may be the thin film BAW resonator. When the acoustic reflective structure includes a Bragg reflective layer, the BAW filter may be the solid-state assembled resonator. For illustration purpose, the BAW filter being the thin film BAW resonator is described in detail below.

The first cavity 120a may be formed by etching the first structural layer 13 through an etching process. However, the present disclosure is not limited thereto. It should be noted that a deposition protection layer or a first bonding layer is disposed between the first structural layer 13 and the logic circuit chip. The first structural layer 13 and the logic circuit chip may be connected through the deposition protection layer formed by a deposition process, or through the first bonding layer. A second bonding interface layer is disposed between the first structural layer 13 and the BAW filter. The first structural layer 13 is bonded and connected to the BAW filter through the second bonding interface layer. The BAW filter is bonded to the first structural layer 13 on the logic circuit chip through a bonding process to form the first cavity 120a. A vertical integration of the BAW filter and the logic circuit chip is achieved at the device fabrication stage, which saves the back-end system level packaging process, simplifies the fabrication process, reduces the packaging volume of the entire system, and substantially improves integration density. The bonding method includes: metal bonding, covalent bonding, adhesive bonding, or fusion bonding. In some embodiments, the first structural layer 13 and the BAW filter are bonded through a bonding layer, The materials of the bonding layer include a photolithographic organic curable film, silicon oxide, silicon nitride, silicon oxynitride, silicon carbonitride, ethyl silicate, or metal.

In some embodiments, for the shape of the first cavity 120a, reference can be made to Embodiment 1. The description thereof is omitted herein.

It should be noted that, by disposing the first structural layer 13 of the first cavity 120a between the logic circuit chip and the BAW filter, the effective resonance region of the piezoelectric stack structure is located in the first cavity 120a. Thus, the vertical integration is achieved, the packaging volume of the entire system is reduced, miniaturization is achieved, and the integration density is substantially improved.

In some embodiments, the first cavity 120a penetrates through the first structural layer 13. The first structural layer 13 includes a photolithographically curable organic film or an oxide layer. In some embodiments, the first structural layer 13 is silicon oxide, and the thickness range of the first structural layer 13 is about 3 to 10 μm, which achieves the bonding of the BAW filter and the logic circuit chip, ensures desired acoustic reflection efficiency of the BAW filter and desired interference isolation effect of the logic circuit chip, and saves the cost. In some other embodiments, the thickness range of the first structural layer 13 may also be higher or lower than this range.

In some embodiments, the passivation layer 12 is arranged between the first structural layer 13 and the logic circuit chip. By disposing the passivation layer 12 on the logic circuit chip, the logic circuit chip may be protected, and the structure strength and device performance of the logic circuit chip may be improved. The passivation layer 12 includes the oxide layer 121 and the etch stop layer 122. The oxide layer 121 is located on the upper surface of the logic circuit chip. The etch stop layer 122 is located on the oxide layer 121. The etch stop layer 122 is provided on the oxide layer 121. For the materials and functions of the oxide layer and the etch stop layer 122, reference can be made to Embodiment 1.

In some other embodiments, the passivation layer 12 may only include one of the oxide layer 121 and the etch stop layer 122. Or the passivation layer 12 may also have other structures, which are not limited here. In some embodiments, the logic circuit chip further includes a substrate 10 and a dielectric layer 20 disposed on the substrate 10.

In some embodiments, the BAW filter is located above the first structural layer 13. The BAW filter includes the supporting substrate 100, the support layer 101 disposed on the surface of the supporting substrate 100, and the piezoelectric stack structure configured to form the second cavity 110a with the supporting substrate 100 and the support layer 101.

Specifically, the orthogonal projections of the first cavity 120a and the second cavity 110a on the piezoelectric stacked structure at least partially overlap with each other, such that such that both the upper and lower surfaces of the effective resonance region are completely exposed in the air, which effectively improves the quality factor of the BAW filter.

For the material of the supporting substrate 100, reference can be made to the description in Embodiment 1.

The support layer 101 is bonded to the supporting substrate 100 and forms the second cavity 110a with the piezoelectric stack structure. The second cavity 110a exposes the supporting substrate 100. In some embodiments, the second cavity 110a is an annular closed cavity. The second cavity 110a can be formed by etching the support layer through an etching process. However, the present disclosure is not limited thereto.

In some embodiments, the shape of the bottom surface of the second cavity 110a is a rectangle. In some other embodiments, the shape of the bottom surface of the second cavity 110a on the first electrode 102 may also be circular, oval, or polygons other than rectangles, such as pentagons, hexagons, etc. The materials of the support layer 101 may be any suitable dielectric material, including but not limited to one of silicon oxide, silicon nitride, silicon oxynitride, and silicon carbonitride. The materials of the support layer 101 and the bonding layer may be the same.

The piezoelectric stack structure is disposed above the second cavity 110a. The piezoelectric stack structure includes the first electrode 102, the piezoelectric layer 103, and the second electrode 104 arranged sequentially. The first electrode 102 is disposed on the support layer 101. The piezoelectric layer 103 is disposed on the first electrode 102. The second electrode 104 is disposed on the piezoelectric layer 103.

In some embodiments, the piezoelectric layer 103 covers the second cavity 110a. It should be understood that the piezoelectric layer 103 is a complete film layer without etching. It does not mean that the piezoelectric layer 103 completely covers the second cavity 110a to form a sealed cavity. Of course, the piezoelectric layer 103 may completely cover the second cavity 110a to form the sealed cavity. The fact that the piezoelectric layer 103 is not etched ensures a certain thickness of the piezoelectric stack structure, such that the BAW filter has a certain structural strength, thereby improving the yield of the BAW filter.

In some embodiments, the surface of the piezoelectric stack structure further includes the first groove 105 and the second groove 106. The first groove 105 is located on the lower surface of the piezoelectric stack structure on the bottom of the side where the second cavity 110a is located, and penetrates through the first electrode 102. The second groove 106 is located on the upper surface of the piezoelectric stacked structure and penetrates through the second electrode 104. The two ends of the first groove 105 are disposed opposite to the two ends of the second groove 106, such that the two junctions of the orthogonal projections of the first groove 105 and the second groove 106 on the supporting substrate 100 meet or may be separated by a gap. In some embodiments, the orthogonal projections of the first groove 105 and the second grove 106 on the supporting substrate 100 are closed figures. The first electrode 102, the piezoelectric layer 103, and the second electrode 104 disposed above the second cavity 120a overlap with each other in the direction perpendicular to the supporting substrate 100. The region being overlapped between the first groove 105 and the second groove 106 is the effective resonance region. The effective resonance region of the BAW filter is defined by the first groove 105 and the second groove 106. The first groove 105 and the second groove 106 penetrate through the first electrode 102 and the second electrode 104, respectively. The piezoelectric layer 103 remains intact without being etched, which ensures the structural strength of the BAW filter and improves the yield of the BAW filter.

In some embodiments, the logic circuit chip is electrically connected to the external circuits through the first electrical connection structure 14 and the fourth electrical connection structure 17, and the BAW filter is electrically connected to the external circuits through the second electrical connection structure 15 and the third electrical connection structure 16. Respectively forming the electrical connection structures for the BAW filter and the logic circuit chip to electrically connect with each other and electrically connect to the external circuits shortens the interconnection distances, increases the signal transmission speeds, and reduces the signal losses, and improves the performance of MEMS devices.

The first electrical connection structure 14 includes the first interconnection hole (not shown) and the first conductive interconnection layer 141 disposed in the first interconnection hole. The first interconnection hole extends from the one side of the supporting substrate 100, and penetrates and extends to the CMOS circuit 11 of the logic circuit chip. The second electrical connection structure 15 includes the second interconnection hole (not shown) and the second conductive interconnection layer 151 disposed in the second interconnection hole. The second interconnection hole extends from the one side of the supporting substrate 100, and penetrates and extends to the first electrode 102 outside the effective resonance region of the piezoelectric stack structure.

The supporting substrate 100 is provided with the interconnection line 18. The first conductive interconnection layer 141 includes the first plug. The second conductive interconnection layer 151 includes the second plug. The first plug and the second plug are electrically connected to the interconnection line 18.

The first electrical connection structure 14 includes the first interconnect hole. The first interconnect hole penetrates from one side of the supporting substrate 100 and extends to the CMOS circuit 11 of the logic circuit chip. The first conductive interconnection layer 141 covers the inner surface of the first interconnection hole and is electrically connected to the interconnection line 18 on the surface of the supporting substrate 100. The second electrical connection structure 15 includes the second interconnection hole. The second interconnection hole penetrates from one side of the supporting substrate 100, extends to the first electrode 102 outside the effective resonance region of the piezoelectric stack structure, and exposes the first electrode 102. The second conductive interconnection layer 151 covers the inner surface of the second interconnection hole and is electrically connected to the interconnection line 18 on the surface of the supporting substrate 100.

It should be noted that the second electrical connection structure 15 is not directly electrically connected to the second electrode 104, but is connected to the first electrode 102 outside the effective resonance region. The second electrical connection structure 15 is electrically connected to the second electrode 104 of the effective resonance region through a conductive interconnection structure (not shown). The third electrical connection structure 16 is electrically connected to the first electrode 102 inside the effective resonance region, and supplies power to the first electrode 102 inside the effective resonance region. It can be seen that the first electrical connection structure 14 and the fourth electrical connection structure 17 are consistent in structure, but are disposed at different positions. The second electrical connection structure 15 and the third electrical connection structure 16 are also consistent in structure, but are disposed at different positions. Thus, the descriptions about the structures of the third electrical connection structure 16 and the fourth electrical connection structure 17 are omitted herein.

It should be noted that each embodiment in the specification is described in a related manner. The same and similar parts of each embodiment can be referred to each other. Each embodiment focuses on the differences from other embodiments.

The beneficial effects of the methods of the present disclosure includes the following. The first structural layer with the first isolation groove is formed on the logic circuit chip. The BAW filter is bonded to the first structural layer on the logic circuit chip through a bonding process to form the first cavity. The vertical integration of the BAW filter and the logic circuit chip is achieved at the device fabrication stage, which saves the back-end system level packaging process, simplifies the fabrication process, reduces the packaging volume of the entire system, and substantially improves the integration density. The BAW filter is bonded to the logic circuit chip at the wafer-level stage of the device fabrication to achieve the batch integration, which saves the substrate wafer in the conventional filter fabrication process, and reduces the production costs. In addition, the fabrication process of the BAW filter is streamlined, and the cavity forming process on the piezoelectric stack structure of the BAW filter is avoided. Thus, the piezoelectric stack structure does not need the pre-configured protection layer and is prevented from being damaged by an etching process, thereby improving the device performance. The effective resonance region of the piezoelectric stack structure is located in the first cavity, such that the upper and lower surfaces of the effective resonance region are completely exposed in the air, which effectively improves the quality factor of the BAW filter.

Further, forming the passivation layer on the logic circuit chip provides the dustproof, waterproof and anticorrosion functions for the logic circuit chip, and prevents the CMOS circuit from being corroded by liquids in the fabrication process or water vapor environment.

Further, before the BAW filter is bonded to the logic circuit chip, the first structural layer is planarized to enhance the bonding strength, which improves the depth uniformity of the first cavity, improves the reflection performance of the first cavity, and improves the performance of the BAW filter.

Further, the thickness of the first structural layer is set to a range between 3 μm and 10 μm, which facilitates the bonding of the BAW filter and the logic circuit chip, ensures the acoustic reflection efficiency of the BAW filter and the interference isolation effect of the logic circuit chip, and saves cost.

Further, the resistivity of the substrate is greater than 1K ohm·cm, which generates a relatively large electrical impedance, reduces interference to the high-frequency electromagnetic waves of the BAW filter, and improves the device performance.

Further, the bonding process for bonding the BAW filter and the logic circuit chip is performed in the vacuum ranging between 1 mbar and 10 mbar, which ensures that the pressure difference between the inside and the outside of the first cavity is in an appropriate range during the bonding process and the pressure difference between the first cavity and the second cavity is balanced to avoid a large one-sided force on the piezoelectric stack structure, and improves the performance of the BAW filter.

Further, the BAW filter and the logic circuit chip respectively form an electrical connection structure to facilitate the electrical interconnection thereof and the electrical connection to the external circuits, which shortens the interconnection distance, increases the signal transmission speed, reduces the signal loss, and improves the performance of the MEMS device.

The beneficial effects of the structures of the present disclosure include the following. By disposing the first structural layer of the first cavity between the logic circuit chip and the BAW filter, the effective resonance region of the piezoelectric stack structure of the BAW filter is located in the first cavity, which achieves the vertical integration, reduces the packaging volume of the whole system, achieves the miniaturization, and substantially improves the integration density.

Further, the BAW filter and the logic circuit chip respectively form an electrical connection structure to facilitate the electrical interconnection thereof and the electrical connection to the external circuits, which shortens the interconnection distance, increases the signal transmission speed, reduces the signal loss, and improves the performance of the MEMS device.

Further, the effective resonance region of the BAW filter is defined by the first groove and the second groove. The first groove and the second groove respectively penetrate the first electrode and the second electrode, and the piezoelectric layer remains intact without being etched, which ensures the structural strength of the BAW filter and improves the yield of the BAW filter.

Further, the passivation layer is provided on the logic circuit chip, which provides the dustproof, waterproof and anticorrosion functions for the logic circuit chip, and improves the device performance.

The above description is merely a description of some embodiments of the present disclosure, and does not limit the scope of the present disclosure. Any changes and modifications made by those of ordinary skill in the field of the present disclosure based on the above disclosures shall fall within the scope of the appended claims.

What is claimed is:

1. A fabrication method of a microelectromechanical systems (MEMS) device, comprising:
providing a logic circuit chip including a substrate and a complementary metal-oxide semiconductor (CMOS) circuit disposed on the substrate, forming a first structural layer on the logic circuit chip, and forming a first isolation groove on the first structural layer;
providing a bulk acoustic wave (BAW) filter including a supporting substrate, a support layer formed on the supporting substrate, and a piezoelectric stack structure, the piezoelectric stack structure forming a second cavity with the supporting substrate and the support layer, and piezoelectric stack structure including a second electrode, a piezoelectric layer, and a first electrode that are sequentially stacked; and
bonding the BAW filter to the first structural layer on the logic circuit chip, such that the first isolation groove is disposed between the logic circuit chip and the BAW filter to form a first cavity where an effective resonance region of the piezoelectric stack structure is located.

2. The fabrication method according to claim 1, wherein:
the first structural layer includes a photolithographically curable organic film, metal, silicon oxide, silicon oxynitride, silicon carbonitride, ethyl silicate, or a combination thereof.

3. The fabrication method according to claim 1, further comprising:
after forming the first structural layer and before bonding the logic circuit chip, planarizing the first structural layer, a thickness of the first structural layer ranging between 3 and 10 μm.

4. The fabrication method according to claim 1, wherein:
resistivity of the substrate is greater than 1K ohm·cm.

5. The fabrication method according to claim 1, wherein:
orthogonal projections of the first cavity and the second cavity on the piezoelectric stack structure partially overlap with each other.

6. The fabrication method according to claim 1, wherein:
the BAW filter and the logic circuit chip are connected through a bonding process; and
the bonding process is performed in a vacuum ranging between 1 mbar to 10 mbar.

7. The fabrication method according to claim 6, wherein:
the bonding process includes: metal bonding, fusion bonding, pressure bonding, adhesion, covalent bonding, and atomic bonding.

8. The fabrication method according to claim 1, wherein forming the first cavity includes:
providing the logic circuit chip;
forming the first structural layer on the logic circuit chip;
etching the first structural layer to form the first isolation groove;
providing the BAW filter; and
bonding the BAW filter to the first structural layer, such that disposing the first isolation groove between the logic circuit chip and the BAW filter forms the first cavity.

9. The fabrication method according to claim 1, before the first structural layer is formed on the logic circuit chip, further comprising:
forming a passivation layer on the logic circuit chip, wherein the passivation layer includes an oxide layer and an etch stop layer, the oxide layer is formed on the logic circuit chip, and the etch stop layer is formed on the oxide layer.

10. The fabrication method according to claim 1, after the BAW filter and the logic circuit chip are bonded, further comprising:
forming a first electrical connection structure to electrically connect the logic circuit chip to an external circuit; and
forming a second electrical connection structure to electrically connect the BAW filter to another external circuit;
wherein forming the first electrical connection structure includes:
forming a first interconnection hole through an etching process, the first interconnection hole penetrating from one side of the supporting substrate and extending to the CMOS circuit of the logic circuit chip; and
forming a first conductive interconnection layer in the first interconnection hole, the first conductive interconnection layer covering an inner surface of the first interconnection hole; and
forming the second electrical connection structure includes:
forming a second interconnection hole through the etching process, the second interconnection hole penetrating from one side of the supporting substrate and extending to the first electrode outside the effective resonance region of the piezoelectric stack structure; and
forming a second conductive interconnection layer in the second interconnection hole, the second conductive interconnection layer covering an inner surface of the second interconnection hole.

11. The fabrication method according to claim 10, after the first electrical connection structure and the second electrical connection structure are formed, further comprising:
forming an interconnection line on a surface of the supporting substrate;
wherein:
the interconnection line is electrically connected to the external circuits;
the first conductive interconnection layer and the second conductive interconnection layer are electrically connected to the interconnection line; and
the first conductive interconnection layer includes a first plug, and the second conductive interconnection layer includes a second plug.

12. A microelectromechanical systems (MEMS) device, comprising:
a logic circuit chip including a complementary metal-oxide semiconductor (CMOS) circuit;
a first structural layer disposed above the logic circuit chip; and
a bulk acoustic wave (BAW) filter disposed above the first structural layer;
wherein:
a bonding interface layer is formed between the BAW filter and the first structural layer;
the BAW filter includes a supporting substrate, an acoustic reflective structure disposed on a surface of the supporting substrate, and a piezoelectric stack structure disposed on the acoustic reflective structure;
the first structural layer includes a first cavity; and
an effective resonance region of the piezoelectric stack structure is disposed in the first cavity.

13. The MEMS device according to claim 12, wherein:
the first cavity penetrates through the first structural layer; and the first structural layer is an oxide layer.

14. The MEMS device according to claim 12, wherein:
a passivation layer is formed between the first structural layer and the logic circuit chip;
the passivation layer includes the oxide layer and an etch stop layer;
the oxide layer is disposed on an upper surface of the logic circuit chip; and
the etch stop layer is disposed on the oxide layer.

15. The MEMS device according to claim 12, wherein:
the acoustic reflective structure includes a support layer disposed on a surface of the supporting substrate and a second cavity enclosed by the supporting substrate, the support layer, and the piezoelectric stack structure; and
the piezoelectric stack structure includes a second electrode, a piezoelectric layer, and a first electrode that are stacked sequentially.

16. The MEMS device according to claim 15, wherein:
the logic circuit chip is electrically connected to the external circuit through the first electrical connection structure and the fourth electrical connection structure; and
the BAW filter is electrically connected to the other external circuit through the second electrical connection structure and the third electrical connection structure.

17. The MEMS device according to claim 16, wherein:
the first electrical connection structure includes a first interconnection hole and a first conductive interconnection layer disposed in the first interconnection hole, the first interconnection hole penetrating from one side of the supporting substrate and extending to the CMOS circuit of the logic circuit chip; and
the second electrical connection structure includes a second interconnection hole and a second conductive interconnection layer disposed in the second interconnection hole, the second interconnection hole penetrating from one side of the supporting substrate and extending to the first electrode outside the effective resonance region of the piezoelectric stack structure.

18. The MEMS device according to claim 17, wherein:
an interconnection line is formed on the supporting substrate;
the first conductive interconnection layer includes a first plug;
the second conductive interconnection layer includes a second plug; and
the first plug and the second plug are electrically connected to the interconnection line.

19. The MEMS device according to claim 15, wherein:
a first groove is disposed at a bottom of the second cavity to penetrate the first electrode;
a second groove is disposed at a position corresponding to the first groove to penetrate the second electrode; and
two junctions of orthogonal projections of the first groove and the second groove on the supporting substrate meet with each other or are separated by a gap.

20. The MEMS device according to claim 12, wherein:
the acoustic reflective structure includes a Bragg reflective layer.
